(19) United States
(12) Patent Application Publication
(10) Pub. No.: US 2001/0013618 A1
(43) Pub. Date: Aug. 16, 2001

(54) SEMICONDUCTOR DEVICE AND METHOD OF FABRICATING THE SAME

(76) Inventors: TOSHIYUKI OASHI, TOKYO (JP); HIROKI SHINKAWATA, TOKYO (JP)

Correspondence Address: MCDERMOTT WILL & EMERY, 600 13TH STREET, N.W., WASHINGTON, DC, 20005-3096, US

(21) Appl. No.: 09/031,555

(22) Filed: Feb. 27, 1998

(30) Foreign Application Priority Data
Aug. 29, 1997 (JP) HEI9-233491

(51) Int. Cl. H01L 29/76; H01L 31/119; H01L 29/94

(52) U.S. Cl. 257/306

(57) ABSTRACT

Lower wiring lines of a semiconductor memory are covered with a SiN film, and a SiO2 interlayer insulating film is formed over the SiN film. When forming a contact hole, an opening is formed first in the SiO2 interlayer insulating film by anisotropic etching, and then a portion of the SiN film in the opening is removed by isotropic etching. Residues of oxide film, if any, are removed by anisotropic etching to complete a contact hole reaching the semiconductor substrate. Over-etching of the semiconductor substrate is prevented in forming the contact hole, and the contact does not penetrate into a semiconductor substrate.

### TECHNICAL FIELD

The present invention relates to a semiconductor device employing self-aligning contacts, and a method of fabricating such a semiconductor device. More specifically, the present invention relates to a semiconductor device provided with contacts of stable characteristics by improvements in a method of forming self-aligning contacts, and a method of fabricating such a semiconductor device.

### BACKGROUND ART

Memory cells have been progressively miniaturized as the storage capacity of the semiconductor memory has been increased, and the diameter of contact holes of memory cells, such as bit line contacts for the memory cells of DRAMs, and distances between wiring lines, such as distances between the transfer gates of DRAM memory cells, have been reduced. Contact holes formed by a photographic process have a limit in accuracy due to a dimensional error or overlapping error of the photographic masks. Hence, there is a possibility that upper wiring lines, such as bit lines of memory cells of a DRAM, may short to gates.

Referring to FIG. 11 showing a wiring structure in a conventional semiconductor device by way of example, there are shown a semiconductor substrate 1, a source/drain region la, an isolating insulation film 2, a gate insulating film 3, gate electrodes 4, an insulating film 5 overlying the gate electrode 4, an insulating film 6 covering the side walls of the gate electrode 4, an interlayer insulating film 10, a bit line 11, and a bit line contact 12. In the conventional semiconductor device, the bit line contact 12 may touch the gate electrode 4 as shown in FIG. 11.

FIG. 12 is a sectional view showing a self-aligning contact employed in solving the problem shown in FIG. 11, in which parts like or corresponding to those shown in FIG. 11 are designated by the same reference characters and description thereof will be omitted to avoid duplication. Shown in FIG. 12 are an insulating film 7 (SiO2 film) formed over the entire surface of the semiconductor substrate 1 so as to cover the insulating films 5 and 6 (SiO2 films), and a SiN film 9 formed on the insulating film 7. In this example, the bit line contact 12 is formed in a contact hole formed in the SiN film 9 so as to reach the source/drain region la formed in the surface of the semiconductor substrate 1.

The use of the self-aligning contact hole prevents short circuit between an upper wiring line and a lower wiring line. However, in the structure shown in FIG. 12, the semiconductor substrate 1 is etched when the contact hole is formed and the bottom of the contact hole lies below the source/drain region 1a and, consequently, junction current between the contact hole and the semiconductor substrate 1 increases.

If the SiN film 9 is etched by anisotropic dry etching to form the contact hole, the SiN film 9 remains on the side wall of the contact hole, which reduces the contact area between the contact hole and the semiconductor substrate 1 and, consequently, contact resistance increases.

FIGS. 13(a), 13(b) and 13(c) illustrate a method of fabricating the conventional semiconductor device shown in FIG. 12, in which parts like or corresponding to those shown in FIG. 12 are designated by the same reference characters and the description thereof will be omitted to avoid duplication.

As shown in FIG. 13(a), a contact hole 10a is formed in a interlayer insulating film 10 (oxide film) by anisotropic dry etching. The oxide/nitride etching selectivity is about 20, and the SiN film 9 is etched at a low etch rate.

Then, as shown in FIG. 13(b), the SiN film 9, i.e., a stopper film, and the underlying oxide film 7 are etched through the contact hole 10a formed in the interlayer insulating film 10 by anisotropic dry etching to form a bit line contact. The ratio of the etching rates of the nitride film and the oxide film to that of the semiconductor substrate 1 is as small as unity, the semiconductor substrate 1 is etched by over etching.

Then, as shown in FIG. 13(c), a bit line 11 and a bit line contact 12 are formed.

The bottom of the bit line contact 12 thus formed lies below the source/drain region 1a, and junction current between the source/drain region la and the semiconductor substrate 1 increases.

Part of the SiN film 9 remains on the side wall of the contact hole, the contact area between the contact hole and the semiconductor substrate 1 is reduced, and contact resistance increases.

As mentioned above, in the conventional semiconductor device fabricating method and the semiconductor device fabricated by the same fabricating method, the semiconductor substrate is etched when forming the contact hole, and hence the contact penetrates the conductive region in the semiconductor substrate, which makes characteristics of the semiconductor device unstable.

### DISCLOSURE OF THE INVENTION

The present invention has been made to solve such a problem in the prior art, and it is an object of the present invention to improve the contact hole forming method and to provide a semiconductor device provided with stable contacts.

According to one aspect of the present Invention, a semiconductor device comprises a semiconductor substrate and a plurality of first conductors formed on the semiconductor substrate. A first insulating film is formed at least over the surfaces of the first conductors. A second insulating film is formed over the entire surface of the semiconductor substrate including the surfaces of the first conductors. A third insulating film is formed on the second insulating film. A second conductor is formed on the third insulating film. Further, contacts extend from the second conductor through the third insulating film and the second insulating film and through spaces between adjacent conductors among the plurality of first conductors to the semiconductor substrate, and a portion of each of the contacts facing the second insulating film is diametrically expanded in the shape of a flange.

In the semiconductor device, the second conductors may be bit lines, and the contacts may be bit line contacts.

In another aspect of the present invention, the semiconductor device further comprises a plurality of third conductors formed in the third insulating film, and the contacts extend through spaces between adjacent conductors among the plurality of third conductors.

In the semiconductor device, the first conductors may be word lines, the third conductors may be bit lines, the second conductors may be storage nodes, and the contacts may be storage node contacts.

In the semiconductor device, the semiconductor substrate may be a silicon wafer, the first insulating film may be a silicon dioxide film, and the second insulating film may be a silicon nitride film.

According to another aspect of the present invention, in a semiconductor device fabricating method, a plurality of first conductors are formed on a semiconductor substrate in a first step. In a second step, a first insulating film is formed over at least the surfaces of the plurality of first conductors. In a third step, a second insulating film is formed over the entire surface of the semiconductor substrate so as to cover the first insulating film. In a fourth step, a third insulating film is formed on the second insulating film. In a fifth step, contact holes are formed in portions of the third insulating film corresponding to spaces between adjacent conductors among the plurality of first conductors so as to reach the second insulating film. In a sixth step, each space having the shape of a flange facing the second insulating film is formed by removing a portion of the second insulating film around each of the contact holes by isotropic etching.

In another aspect of the present invention, in the semiconductor device fabricating method, parts of the first insulating film remaining in the contact holes are removed in a seventh step by anisotropic etching after completion of the sixth step.

In another aspect of the present invention, in the semiconductor device fabricating method, in an eighth step, a second conductor is formed to cover the contact holes on the third insulting film and to extend into the contact holes after completion of the sixth or the seventh step.

In the semiconductor device fabricating method, the semiconductor substrate may be a silicon wafer, the first insulating film may be a silicon dioxide film, and the second insulating film may be a silicon nitride film.

Other and further objects, features and advantages of the invention will appear more fully from the following description.

### BRIEF DESCRIPTION OF DRAWINGS

FIG. 1 shows a sectional view of a semiconductor device according to a first embodiment of the present invention.

FIGS. 2(a) through 4(d) illustrate steps of a fabricating method of a semiconductor device according to a second embodiment of the present invention.

FIG. 5 shows a sectional view of a semiconductor device in a third embodiment of the present invention.

FIGS. 6 and 7 show a fabricating method of a semiconductor device according to a fourth embodiment of the present invention.

FIG. 8 shows a sectional view of a semiconductor device according to a fifth embodiment of the present invention.

FIG. 9 shows a sectional view of a semiconductor device according to a sixth embodiment of the present invention.

FIG. 10 shows a sectional view of a semiconductor device according to a seventh embodiment of the present invention.

FIG. 11 shows a wiring structure in a conventional semiconductor device.

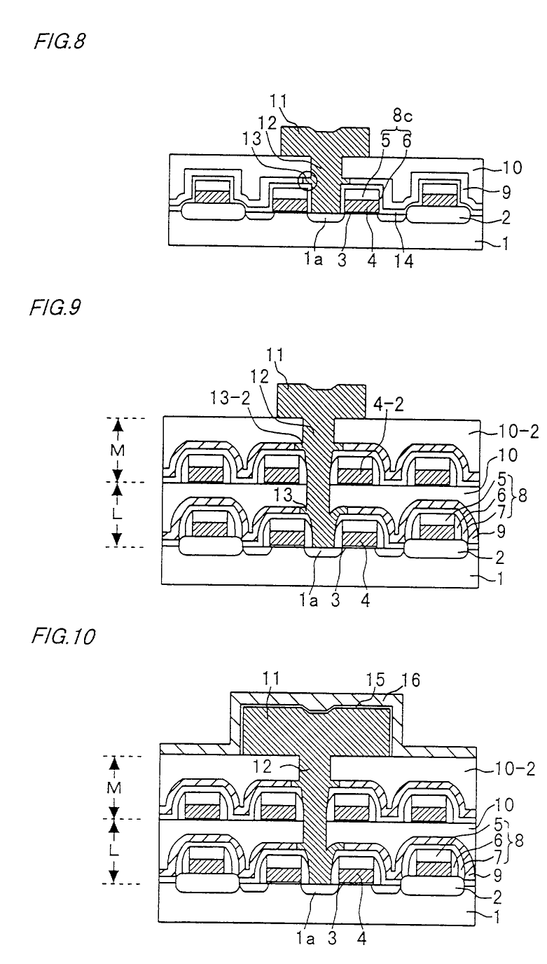

FIG. 12 shows a sectional view of a self-aligning contact in a conventional semiconductor device.

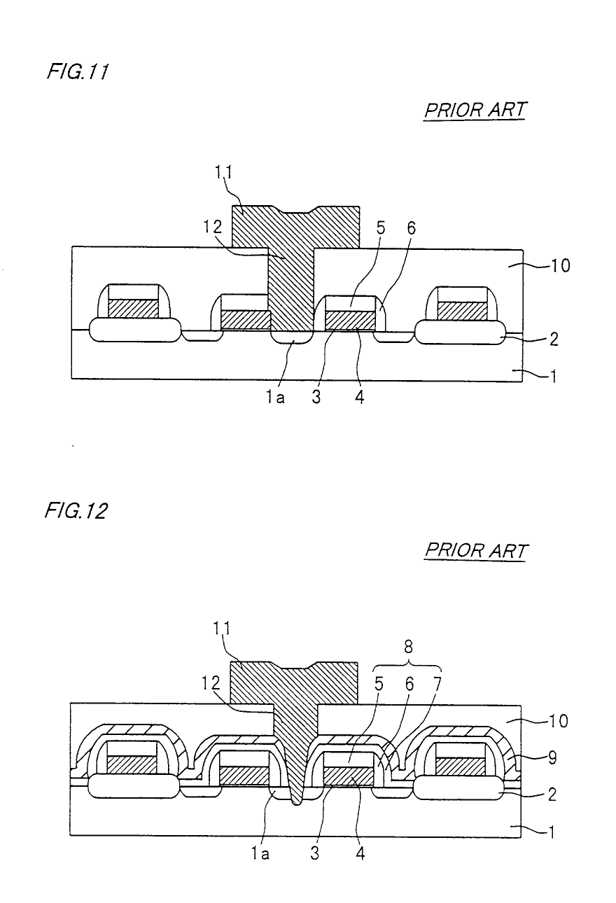

FIGS. 13(a), 13(b) and 13(c) illustrate a method of fabricating a conventional semiconductor device.

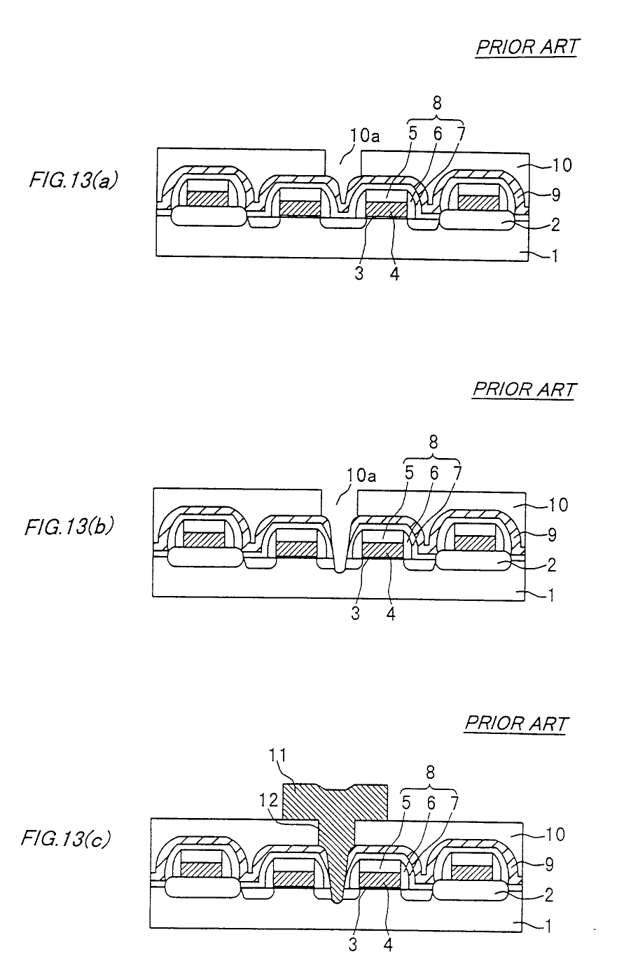

### BEST MODE FOR CARRYING OUT THE INVENTION

Preferred embodiments of the present invention will be described hereinafter with reference to the accompanying drawings, in which like parts are designated by the same reference characters.

First Embodiment

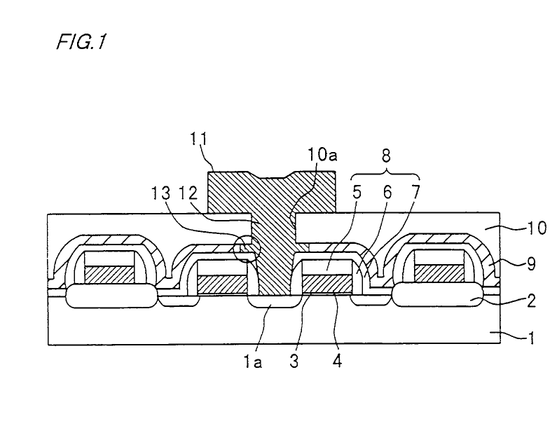

Referring to FIG. 1 showing a semiconductor device in a first embodiment according to the present invention, there are shown a semiconductor substrate 1 (Si substrate), an isolating insulation film 2 (SiO2 film), a gate insulating film 3, gate electrodes 4 (first conductors), an insulating film 5 (SiO2 film) covering the gate electrodes 4, a side wall insulating film 6 (SiO2 film) covering the side walls of the gate electrodes 4, an insulating film 7 (underlying SiO2 film) formed over the entire surface of the semiconductor substrate 1 so as to cover the insulating films 5 and 6. The insulating films 5, 6 and 7 form a first insulating film 8 covering the gate electrodes 4.

Also shown in FIG. 1 are a second insulating film 9 (SiN film) overlying the first insulating film 8, and a third insulating film 10 (SiO2 film) formed as an interlayer insulating film on the second insulating film (SiN film).

A bit line 11 as a second conductor is formed so as to cover a contact hole 10a formed in the third insulating film 10. A bit line contact 12 is formed in the contact hole 10a so as to extend from the bit line 11 through the insulating film 7 and a space formed in the side wall insulating film 6 to the semiconductor substrate 1. The bit line contact 12 has an expansion 13 having the shape of a flange, such as a circular flange, formed by expanding a portion thereof corresponding to the second insulating film 9. The bottom of the bit line contact 12 is in electrical contact with a conductive region 1a (source/drain region) formed in the surface of the semiconductor substrate 1.

In the semiconductor device in the first embodiment thus constructed, the bit line contact 12 has the expansion 13 having the shape of a flange at a position corresponding to the second insulating film 9, the bit line contact 12 in effect does not penetrate into the semiconductor substrate 1, and the bottom of the bit line contact 12 is in electrical contact with the surface of the semiconductor substrate 1. Accordingly, stable electrical connection of the bit line 11 to the conductive region la is achieved, and hence the semiconductor device has stable characteristics.

Portions of the first insulating film 8 and the second insulting film 9 corresponding to the bit line contact 12 are removed, the contact area of the bit line contact 12 is increased and contact resistance is reduced.

Second Embodiment

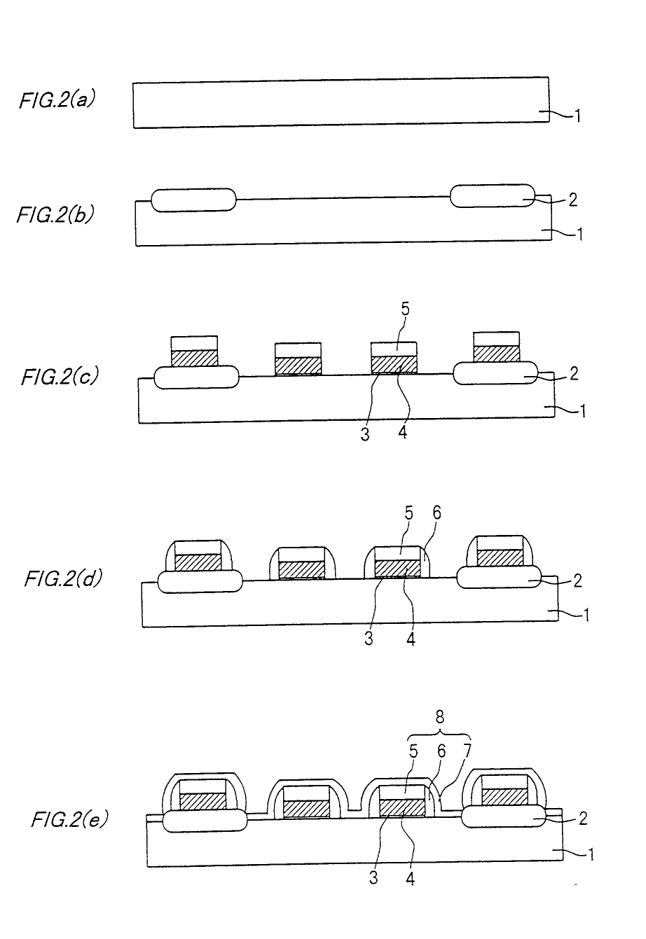

A semiconductor device fabricating method in a second embodiment according to the present invention as applied to fabricating the semiconductor device in the first embodiment will be described with reference to FIGS. 2 to 4. FIGS. 2(a) through 4(d) illustrate a series of steps of the semiconductor device fabricating method.

First, a semiconductor substrate 1 (Si substrate) as shown in FIG. 2(a) is made.

Then, an isolating insulation film 2, such as a LOCOS oxide film, is formed on the semiconductor substrate 1 as shown in FIG. 2(b).

A thin insulating film 3 of, for example, 10 nm in thickness is formed on the semiconductor substrate 1 as shown in FIG. 2(c). The insulating film 3 is a SiO2 film serving as a gate insulating film.

Then, a plurality of first conductors 4 of, for example, 50 nm in thickness, coated with an insulating film 5 of, for example, 50 nm are formed on the insulating film 3 (Seep 1). The conductors 4 is, for example, 0.25 âm in width, and intervals between adjacent conductors 4 are, for example, 0.35 âm. The insulating film 5 is a SiO2 film formed by CVD (chemical vapor deposition) . The first conductors 4 which serve as gate electrodes are formed by processing a polysilicon film or a laminated film consisting of a polysilicon film and a metal silicide film, such as a WSi film or the like.

Then, as shown in FIG. 2(d), a side wall insulating film 6 of, for example, 50 nm in thickness is formed so as to cover the side walls of the first conductors 4 and the insulating film 5. In this embodiment, the side wall insulating film 6 is a SiO2 film.

Then, as shown in FIG. 2(e), an insulating film 7 (underlying oxide film) of, for example, 20 nm in thickness is deposited over the entire surface of the semiconductor substrate 1 by CVD. The insulating film 5 formed on the first conductors 4 (gate electrodes), the side wall insulating film 6 and the insulating film 7 constitute a first insulating film 8 covering the first conductors 4 (gate electrodes) (Step 2).

Then, as shown in FIG. 3(a), a second insulating film 9 (stopper film) of, for example, 50 nm in thickness is formed over the entire surface of the first insulating film 8 (Steps 3). In this embodiment, the second insulating film 9 is a SiN film deposited by CVD.

Then, as shown in FIG. 3(b), a third insulating film 10, i.e., an interlayer insulating film of SiN is formed on the second insulating film 9 (Step 4).

Then, as shown in FIG. 3(c), a photoresist film 10b is formed so as to cover the third insulating film 10 entirely, the photoresist film 10b is patterned to form an opening 10c of, for example, 0.30 âm in diameter. The opening 10c is used for forming a bit line contact.

Then, as shown in FIG. 3(d), a portion of the third insulating film 10 (interlayer insulating film) corresponding to the opening 10c formed in the photoresist film 10b is removed by anisotropic dry etching to form a contact hole 10a (Step 5). Since the oxide/nitride etching selectivity is about 20, the second insulating film 9 (SiN film) is etched at a low etch rate.

Then, as shown in FIG. 4(a), the photoresist film 10b is removed. The foregoing steps are not different from those of the conventional semiconductor device fabricating method.

Then, as shown in FIG. 4(b), a portion of the second insulating film 9 (stopper SiN film) is removed in the contact hole 10a formed in the third insulating film 10 (interlayer insulating film) by isotropic wet etching using hot phosphoric acid (Step 6). A portion of the second insulating film 9 enclosed by a circle in FIG. 4(b) is etched laterally and an annular space is formed. Since the nitride/oxide selectivity of hot phosphoric acid is one hundred or above, the insulating film 7 (underlying oxide film) is etched only slightly.

Then as shown in FIG. 4(c), a portion of the first insulating film 8 including the insulating film 7 is removed in the contact hole 10a by anisotropic dry etching in a self-aligning mode so that the contact hole 10a extends downward without exposing the first conductors 4, i.e., gate electrodes. (Step 7). Since the selectivity of the anisotropic dry etching of the oxide to the silicon (i.e., of the first insulating film 8 to the semiconductor substrate 1) is ten or above, the surface of the semiconductor substrate 1 is not etched significantly.

As shown in FIG. 4(d), a contact 12 is formed so as to fill up the contact hole 10a, and a second conductor 11 of, for example, 100 nm in thickness is formed on the contact 12 so as to cover the contact hole 10a. The second conductor 11 is a polysilicon film or a laminated film of a polysilicon film and a metal silicide film, such as a WSi film.

The contact 12 is formed of polysilicon and has an expansion 13 having the shape of a flange, such as a circular flange, formed by expanding a portion thereof corresponding to the second insulating film 9 (Step 8). The bottom of the contact 12 is in electrical contact with a conductive region 1a (FIG. 1) formed in the surface of the semiconductor substrate 1.

In this embodiment, the second conductor 11 serves as a bit line, and the contact 12 serves as a bit line contact.

In the semiconductor device thus fabricated by the second embodiment of the present invention, the upper self-aligning contact can be connected to the semiconductor substrate 1 so that the same may not touch the first conductor 4 (lower wiring line or word line), the surface of the semiconductor substrate 1 is etched only slightly, and the stable contact can be formed.

Since a portion corresponding to the contact 12 of the second insulating film 9 (SiN film) overlying the first insulating film 8 is removed, the contact area of the contact 12 on the semiconductor substrate 1 is large and hence contact resistance is low.

Third Embodiment

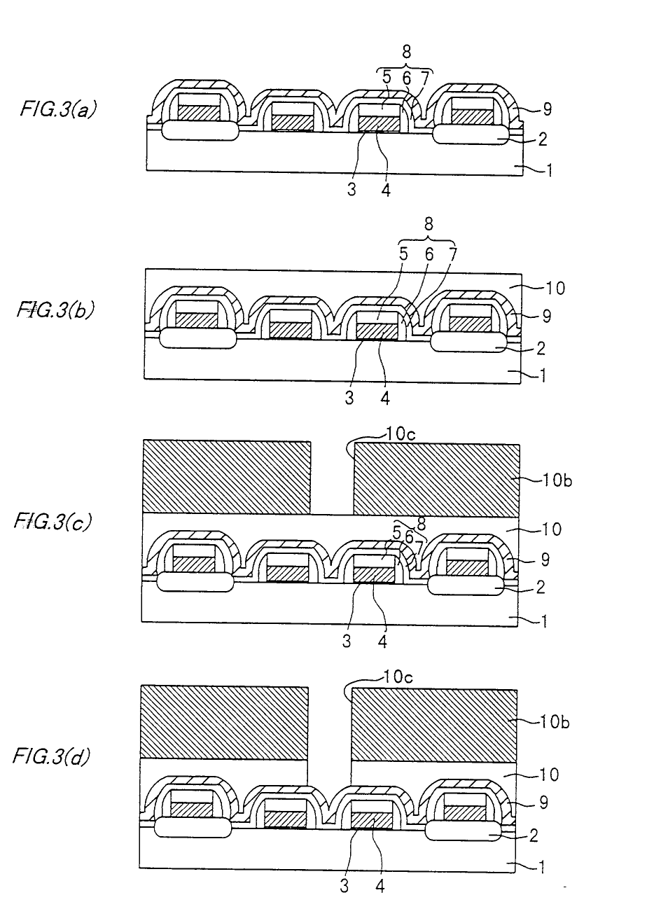

FIG. 5 is a sectional view of a semiconductor device in a third embodiment according to the present invention. The semiconductor device shown in FIG. 5 is provided with a first insulating film 8a consisting of insulating films 5 and 6 instead of the first insulating film 8 of the semiconductor device shown in FIG. 1, consisting of the insulating films 5, 6 and 7.

A second insulating film 9 (SiN film) is formed over the entire surface of a semiconductor substrate 1 so as to cover the first insulating film 8a. A contact 12 penetrates a third insulating film 10 (interlayer insulating film) and the second insulating film 9, and reaches the surface of the semiconductor substrate 1.

The contact 12, similarly to that employed in the first embodiment, has an expansion 13 having the shape of a flange, such as a circular flange, formed by expanding a portion thereof corresponding to the second insulating film 9. The bottom of the contact 12 is in electrical contact with a conductive region 1a (source/drain region) formed in the surface of the semiconductor substrate 1.

The semiconductor device in the third embodiment is the same in effects and in other respects as the semiconductor device in the first embodiment, and hence further description thereof will be omitted to avoid duplication.

Fourth Embodiment

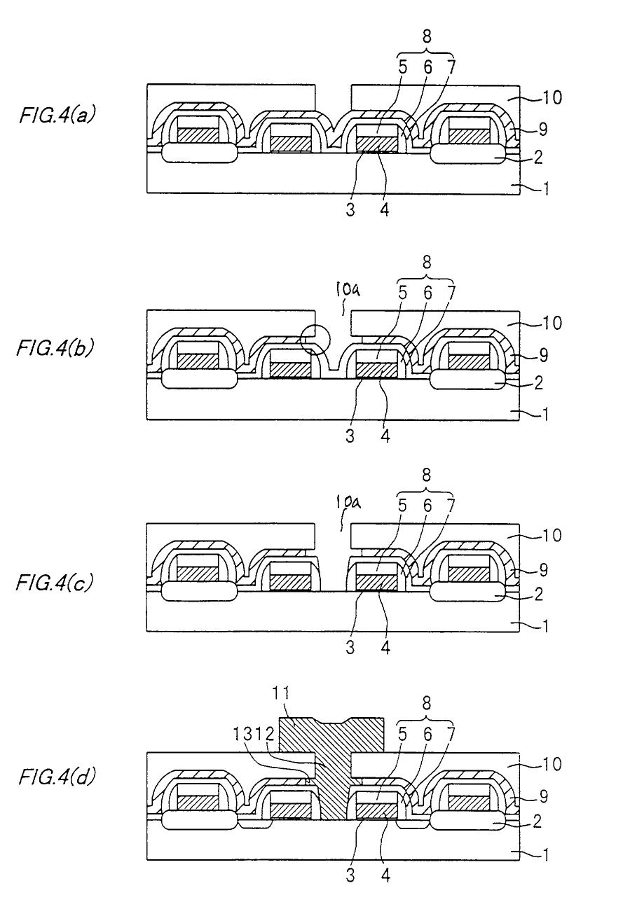

A semiconductor device fabricating method in a fourth embodiment according to the present invention as applied to fabricating the semiconductor device in the third embodiment will be described with reference to FIGS. 6 and 7.

Steps similar to chose illustrated in FIGS. 2(a) through 2(d) are carried out. In the fourth embodiment, a first insulating film 8a consists of the insulating film 5 formed on the first conductor 4, and the side wall insulating film 6 shown in FIG. 2(d) (Step 2).

Then, as shown in FIG. 6(a), a second insulating film 9 (stopper SiN film) is formed over the entire surface of the first insulating film 8a (Steps 3). In this embodiment, the second insulating film 9 is deposited by CVD.

Then, as shown in FIG. 6(b), a third insulating film 10, i.e., a interlayer insulating film of SiN, is formed on the second insulating film 9 (Step 4).

Then, as shown in FIG. 6(c), a photoresist film 10b is formed so as to cover the third insulating film 10 entirely, and the photoresist film 10b is patterned to form an opening 10c. The opening 10c is used for forming a bit line contact.

Then, as shown in FIG. 6(d), a portion of the third insulating film 10 (interlayer insulating film corresponding to the opening 10c formed in the photoresist film 10b is removed by anisotropic dry etching to form a contact hole 10a (Step 5). Since the oxide to the nitride etching selectivity is about twenty, the second insulating film 9 (SiN film) is etched at a low etch rate.

Then, as shown in FIG. 7(a), the photoresist film 10b is removed. The foregoing steps are not different from those of the conventional semiconductor device fabricating method.

Then, as shown in FIG. 7(b), a portion of the second insulating film 9 (stopper SiN film) in removed in the contact hole 10a formed in the third insulating film 10 (interlayer insulating film) by isotropic wet etching using hot phosphoric acid (Step 6). A portion of the second insulating film 9 enclosed by a circle in FIG. 7(b) is etched laterally and an annular space is formed. Since nitride to oxide selectivity of hot phosphoric acid is one hundred or above, the first insulating film 8a is etched only slightly; that is self-aligned etching is carried out without exposing the first conductors 4 and slightly etching the semiconductor substrate 1.

As shown in FIG. 7(c), a second conductor 11 and a contact 12 are formed so as to fill up the contact hole 10a (Step 8). The contact 12 has an expansion 13 having the shape of a flange, such as a circular flange, and formed by expanding a portion thereof corresponding to the second insulating film 9. The bottom of the contact 12 is in electrical contact with a conductive region la (FIG. 5) formed in the surface of the semiconductor substrate 1.

In this embodiment, the second conductor 11 serves as a bit line, and the contact 12 serves as a bit line contact.

The semiconductor device fabricating method in the fourth embodiment of the present invention does not have the step of forming the insulating film 7 and the step of forming an opening in the insulating film 7 of the semiconductor device fabricating method in the second embodiment, and the former semiconductor device fabricating method is the same in other respects as the latter semiconductor device fabricating method. The semiconductor device fabricating method in the fourth embodiment is able to connect the upper self-aligning contact to the semiconductor substrate 1 so that the upper self-aligning contact may not touch the first conductor 4 (lower wiring line or word line), and to form a stable contact so that the surface of the semiconductor substrate 1 is etched only slightly.

Since a portion corresponding to the contact 12 of the second insulating film 9 (SiN film) overlying the first insulating film 8a is removed, the contact area of the contact 12 on the semiconductor substrate 1 is large and hence contact resistance is low.

Fifth Embodiment

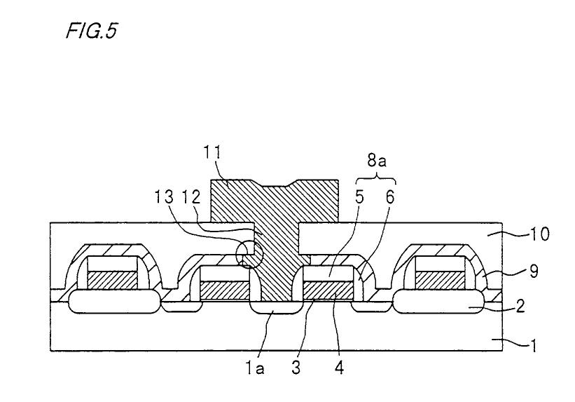

FIG. 8 is a semiconductor device in a fifth embodiment according to the present invention.

The semiconductor device shown in FIG. 8 is not provided with any film corresponding to the side wall insulating film 6 of the semiconductor device shown in FIG. 5, and is provided with a thin insulating film 14 (thin SiO2 film) formed so as to cover the surfaces including the side walls of first conductors 4 and an insulating film 5.

A second insulating film 9 (SiN film) is formed over the entire surface of a semiconductor substrate 1 so as to cover the thin insulating film 14. A contact 12 is formed so as to penetrate an interlayer insulating film 10 and the second insulating film 9 (SiN film) and to be electrically connected to the surface of the semiconductor substrate 1.

The contact 12 has an expansion 13 having the shape of a flange, such as a circular flange, formed by expanding a portion thereof corresponding to a second insulating film 9. The bottom of the contact 12 is in electrical contact with a conductive region 1a (source/drain region) formed in the surface of the semiconductor substrate 1. The semiconductor device in the fifth embodiment has the same characteristics as those of the semiconductor device shown in FIG. 5.

The semiconductor device in the fifth embodiment is the same in other respects as that shown in FIG. 1, and hence further description thereof will be omitted to avoid duplication. The effect of the fifth embodiment is the same as that of the first embodiment.

Sixth Embodiment

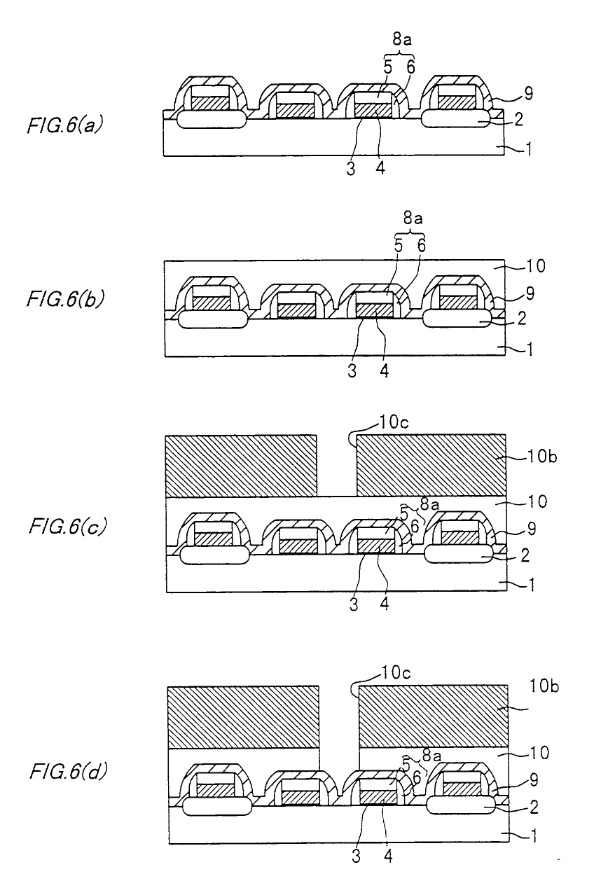

FIG. 9 is a sectional view of a semiconductor device in a sixth embodiment according to the present invention.

In the semiconductor device shown in FIG. 9, the wiring structure of a lower layer L is substantially the same as that of the semiconductor device in the first embodiment.

The wiring structure of a middle layer M is formed on the lower layer L. The wiring structure of the middle layer M is the same as that of the semiconductor device in the first embodiment, except that the former is formed on a third insulating film 10. The middle layer M has third conductors 4-2, a third insulating film 10-2, and a flange 13-2 of a contact 12.

A second conductor 11 is formed on an insulating film 10-2 of the middle layer M. A contact 12 extends from the second conductor 11 through the third insulating film 10-2 and the lower third insulating film 10 to a semiconductor substrate 1. The contact 12 extends through a space between adjacent third conductors 4-2 of the middle layer M and a space between adjacent lower third conductors 4 of the lower layer L to a conductive region la formed in the surface of the semiconductor substrate 1.

Suppose that the lower third insulating film 10 and the middle third insulating film 10-2 are regarded inclusively as a third insulating film. Then, it is considered that the conductors 4-2 of the middle layer M are formed in the third insulating film. Although the wiring structure of the middle layer M is the same as that of the lower layer L in the semiconductor device shown in FIG. 9, the former need not necessarily be the same as the latter.

A flange 13-2 formed in a portion of the contact 12 in the middle layer may be omitted.

In the semiconductor device in the sixth embodiment thus constructed, the contact 12 has an expansion having the shape of a flange, such as a circular flange, formed by expanding a portion thereof corresponding to a second insulating film 9, and the bottom of the contact 12 is in electrical contact with the surface of the semiconductor substrate 1 substantially without hollowing the semiconductor substrate 1. Therefore, the contact 12 is in stable contact with a conductive region 1a formed in the surface of the semiconductor substrate 1, and hence the semiconductor device has stable characteristics.

Since portions of the first insulating film 8 (oxide film) and the second insulating film (SiN film) corresponding to the contact 12 are removed, the contact area of the contact 12 is large and contact resistance is low.

The semiconductor device shown in FIG. 9 can be fabricated by the semiconductor device fabricating method in the second embodiment, except that the semiconductor device shown in FIG. 9 needs steps of forming the wiring structures in two layers. The second insulating film 9 of the lower layer L is etched by isotropic etching, and the second insulating layer 9-2 of the middle layer M may be etched by either isotropic etching or anisotropic etching. Other steps of fabricating the semiconductor device in the sixth embodiment may be understood when reference is made to the second embodiment, and hence description thereof will be omitted.

Seventh Embodiment

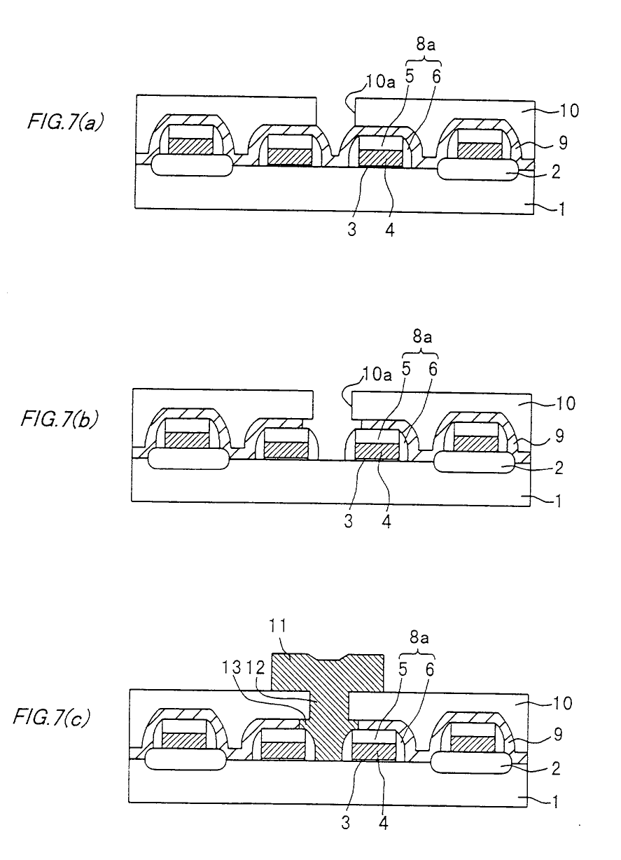

FIG. 10 is a sectional view of a semiconductor device in a seventh embodiment according to the present invention, which is similar in construction to that shown in FIG. 9.

The semiconductor device shown in FIG. 10 differs from that shown in FIG. 9 in that a third conductor 11 is formed of large size to use the same also as a lower electrode of a capacitor. In FIG. 10, indicated at 15 is a dielectric film for the capacitor and at 16 is an upper electrode for the capacitor. The semiconductor device shown in FIG. 10 is similar in other respects as that shown in FIG. 9, and hence further description thereof will be omitted.

The semiconductor device in the seventh embodiment is suitable for use as a semiconductor memory using the lower conductors 4 as word lines, conductors 4-2 in the middle layer M as bit lines, the third conductor 11 as a storage node, and the contact 12 as a storage node contact.

The seventh embodiment provides the same effects as those provided by the sixth embodiment.

A method of fabricating the semiconductor device of FIG. 10 may be readily understood from the method of fabricating the semiconductor device of FIG. 9, and hence description thereof will be omitted to avoid duplication.

The effects and advantages of the present invention may be summarized as follows. According to the present invention, as is apparent from the foregoing description, the contact has a flange-shaped expansion and a sufficiently great diameter, and the bottom of the contact is in contact with the surface of the semiconductor substrate substantially without hollowing the semiconductor substrate. Accordingly, the contact does not short the upper wiring line to the lower wiring line, hollowing of the surface of the semiconductor substrate when forming the contact hole can be avoided, stable connection of the contact and the conductive region of the semiconductor substrate can be achieved, and the semiconductor device has stable characteristics.

Obviously many modifications and variations of the present invention are possible in the light of the above teachings. It is therefore to be understood that within the scope of the appended claims the invention may by practiced otherwise than as specifically described.

What is claimed is:

1. A semiconductor device comprising:
a semiconductor substrate;
a plurality of first conductors formed on the semiconductor substrate;
a first insulating film formed over at least the surfaces of the first conductors;
a second insulating film formed over the entire surface of the semiconductor substrate including the surfaces of the first conductors;
a third insulating film formed on the second insulating film;
a second conductor formed on the third insulating film; and
contacts extending from the second conductor through the third insulating film and the second insulating film and through spaces between adjacent conductors among the plurality of first conductors to the semiconductor substrate, a portion of each of the contacts facing the second insulating film being diametrically expanded in the shape of a flange.

2. The semiconductor device according to claim 1, wherein the first conductors are word lines, the second conductors are bit lines, and the contacts are bit line contacts.

3. The semiconductor device according to claim 1 further comprising a plurality of third conductors formed in the third insulating film, wherein the con-acts extend through spaces between adjacent conductors among the plurality of third conductors.

4. The semiconductor device according to claim 3, wherein the first conductors are word lines, the third conductors are bit lines, the second conductors are storage nodes, and the contacts are storage node contacts.

5. The semiconductor device according to any one of claim 1, wherein the semiconductor substrate is a silicon wafer, the first insulating film is a silicon dioxide film, and the second insulating film is a silicon nitride film.

6. A semiconductor device fabricating method comprising:
a first step of forming a plurality of first conductors on a semiconductor substrate;
a second step of forming a first insulating film over surfaces of at least the plurality of first conductors;
a third step of forming a second insulating film over the entire surface of the semiconductor substrate so as to cover the first insulating film;
a fourth step of forming a third insulating film on the second insulating film;
a fifth step of forming contact holes in portions of the third insulating film corresponding to spaces between adjacent conductors among the plurality of first conductors so as to reach the second insulating film; and
a sixth step of forming an expanded space having the shape of a flange facing the second insulating film by removing a portion of the second insulating film around each of the contact holes by isotropic etching.

7. The semiconductor device fabricating method according to claim 6 further comprising a seventh step of removing parts of the first insulating film remaining in the contact holes by anisotropic etching after completion of the sixth step.

8. The semiconductor device fabricating method according to claim 6, further comprising an eighth step of forming a second conductor covering the contact holes on the third insulating film so as to extend into the contact holes after the completion of the sixth or the seventh step.

9. The semiconductor device fabricating method according to claim 6, wherein the semiconductor substrate is a silicon wafer, the first insulating film is a silicon dioxide film and the second insulating film is a silicon nitride film.
